(19) United States
(12) Patent Application Publication
(10) Pub. No.: US 2019/0035709 A1
(43) Pub. Date: Jan. 31, 2019

(54) ELECTRONIC MODULES

(71) Applicant: HEWLETT PACKARD ENTERPRISE DEVELOPMENT LP, Houston, TX (US)

(72) Inventor: Gregg B Lesartre, Fort Collins, CO (US)

(21) Appl. No.: 16/072,971

(22) PCT Filed: Jan. 26, 2016
(86) PCT No.: PCT/US2016/014884

§ 371 Date: Jul. 26, 2018

(51) Int. Cl. H01L 23/367; H01L 23/473; H01L 23/467; H05K 1/18

(52) U.S. Cl. CPC H01L 23/3672; H01L 23/473; H01R 12/737; H05K 1/18; H01L 23/467

(57) ABSTRACT

An example electronic device includes at least two electronic modules. Each electronic module includes a printed circuit board, heat generating components, and a heat spreader. The heat generating components are disposed on first and second surfaces of the printed circuit board. The heat spreader is disposed on the heat generating components opposite the printed circuit board. The heat spreader includes a base and fins extending from the base. The fins on a first side of a first of the at least two electronic modules extend toward a second of the at least two electronic modules. Fins on a second side of the second of the at least two electronic modules extend toward the first of the at least two electronic modules to interdigitate and share volumetric space between the printed circuit boards of the first and second of the at least two electronic modules.

### BACKGROUND

Increased power of integrated circuit chips, and the modules containing the chips, increases processor performance and heat generated in densely packed memory designs. Chip count and functionality on memory modules continue to increase, while the spacing between modules is minimized. This trend poses cooling challenges.

### BRIEF DESCRIPTION OF THE DRAWINGS

FIG. 1A is a side view of an electronic module according to an example of the present disclosure.

FIG. 1B is a cross-sectional view of the electronic module according to the example of FIG. 1A of the present disclosure.

FIG. 2 is a perspective view of a pair of electronic modules according to an example of the present disclosure.

FIG. 3 is a cross-sectional view of an electronic device including electronic modules according to an example of the present disclosure.

FIG. 4 is a flow chart illustrating an example method for cooling an electronic subsystem in accordance with aspects of the present disclosure.

### DETAILED DESCRIPTION

In the following detailed description, reference is made to the accompanying drawings which form a part hereof, and in which is shown by way of illustration specific examples in which the disclosure may be practiced. It is to be understood that other examples may be utilized and structural or logical changes may be made without departing from the scope of the present disclosure. The following detailed description, therefore, is not to be taken in a limiting sense, and the scope of the present disclosure is defined by the appended claims. It is to be understood that features of the various examples described herein may be combined, in part or whole, with each other, unless specifically noted otherwise.

In many cases, the electrical components in processors are cooled by air moving in parallel airflow paths, usually front-to-back, impelled by one or more air moving devices (e.g., fans or blowers). In some cases it may be possible to handle increased power dissipation by providing greater airflow, for example, through the use of a more powerful air moving device or by increasing the rotational speed (i.e., RPM) of an existing air moving device. Heat is typically carried from the electronic components by the air, or other fluid, passing through and exiting the processing subsystem or system. The fluid absorbs the heat dissipated by the components/modules to an outside environment, whether air or other liquid-coolant. The ability to cool integrated circuit chips, and the modules containing the chips, is a function of the volume of air, or coolant flow, and the surface area on each face of the module available to transfer heat to the passing coolant (e.g., air or liquid).

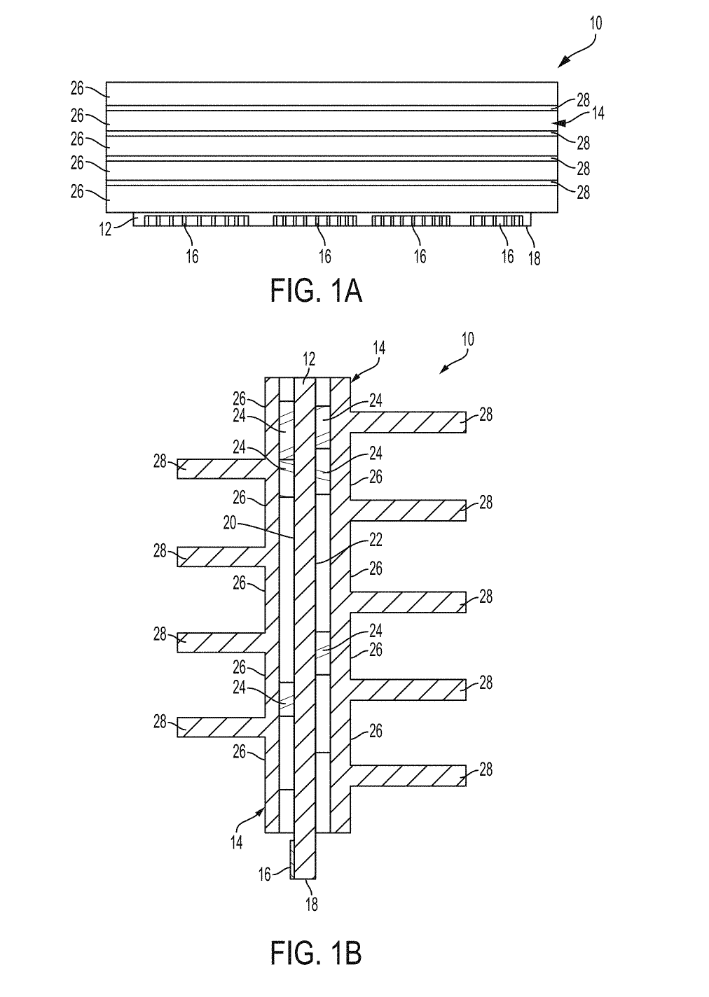

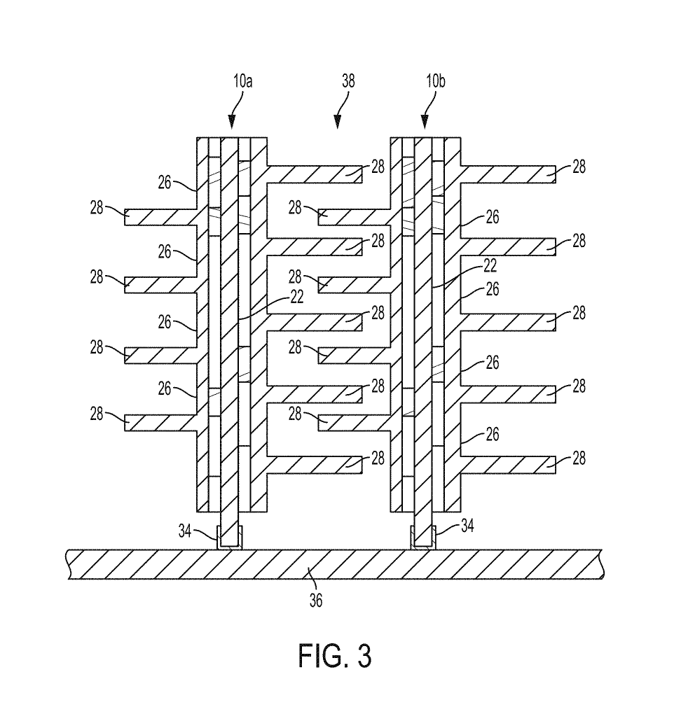

FIGS. 1A and 1B illustrate side and cross-sectional views of an electronic module 10 in accordance with aspects of the present disclosure. Electronic module 10 includes a printed circuit board 12, electronic components 24, and a heat spreader 14. Electrical contacts 16 along an edge 18 of printed circuit board 12 allow mounting memory module 10 in a mating socket, generally perpendicular to a surface of a motherboard (see, e.g., FIG. 3). Printed circuit board 12 has a first surface 20 and an opposing second surface 22. Electronic components 24 can be included on one or both of first and second surfaces 20, 22 of printed circuit board 12. In some high-density electronic modules 10, electronic components 24 such as memory chips, for example, are stacked on printed circuit board 12, where each stack contains multiple memory chips stacked on top of each other. For example, each stack can include two memory chips, one arranged in a first layer and one arranged in a second layer of the stack.

Electronic module 10 includes heat spreader 14 thermally coupled to electronic components 24 to be cooled. Heat spreader 14 includes a base 26 and fins 28 extending in a direction away from base 26. Fins 28 are coupled to, or part of, heat spreader 14 coupled to at least one electronic component 24 of the plurality of electronic components 24 on printed circuit board 12 of electronic module 10. Multiple fins 28 extend from, and are spaced along, base 26. Fins 28 and base 26 of heat spreader 14 provide surface area available to contact with the cooling medium, or cooling fluid, surrounding and passing by heat spreader 14. Fins 28 add surface area to the surface area provided by base 26 for heat conduction from the surface of heat spreader 14 to the fluid (e.g., air or liquid coolant). Fins 28 facilitate cooling of heat generated by electronic components 24 by providing additional surface area for heat conductance to the fluid. Thermal adhesive or thermal grease can be included between electrical components 24 on printed circuit board 12 and heat spreader 14 to fill gaps and provide thermal connection between electrical components 24 and heat spreader 14. Heat, or thermal energy, generated by electrical components 24 is transferred from heat spreader 14 to the fluid medium. Heat spreader 14 is made of highly thermally conductive material. In one example, base 26 and fins 28 on each surface 22, 24, respectively, of printed circuit board 12 are formed together of the same material. In one example, fins 28 and base 26 are formed from a sheet of conductive material bent or otherwise formed into the desired shape.

Electronic module 10 can be a memory module, an input-output module, a high density compute module, a switch module, for example. In one example, module 10 is a dual inline memory module (DIMM). In a DIMM, electrical components 24, such as semiconductor memory integrated circuits and capacitors are mounted on each face of printed circuit board 12. Heat generated in electrical components 24 is radiated from the surface of electrical components 24. Heat spreader 14 disposed on the respective surface 20, 22 is configured to thermally couple with the electronic components 24 on the respective surface 20, 22.

In an example multiple dual inline memory modules (DIMMs) 10, modules 10 can collectively maximize the heat dissipation of heat generating electronic components 24 housed on DIMMs 10 into a fluid flow. DIMMs 10, in particular, fins 28 on DIMMs 10 can collectively direct, or channel, the flow of fluid over and between DIMMs 10 in order to optimize the heat dissipation. For example, the fluid flow can be divided and directed to cool specific components 24.

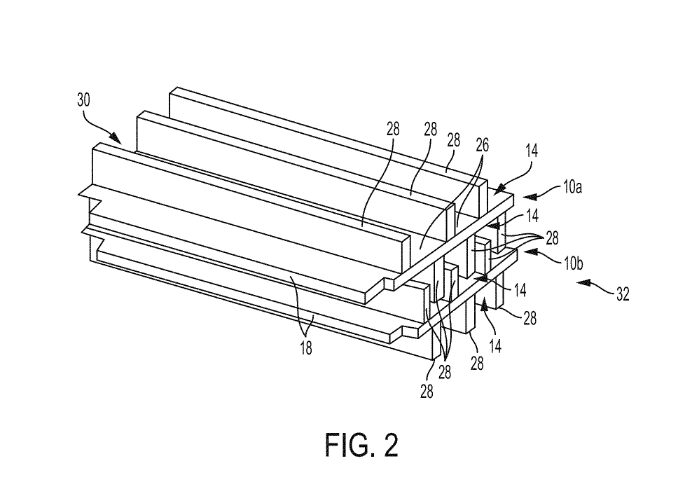

FIG. 2 illustrates a perspective view of a pair of electronic modules 10a, 10b according to an example of the present disclosure. Multiple thermally conductive fins 28 of a plurality of electronic modules 10 are interleaved with fins 28 of adjacent electronic modules 10. The shape of base 26 and fins 28 of heat spreader 14 complements the shape of adjacent memory module 10 heat spreader 14 base 26 and fins 28 to collectively guide the gas (e.g., air) or liquid coolant and maximize the surface area on each electronic module 10 and fluid flow between memory modules 10 to dissipate heat. Fins 28 are configured to be interposed between adjacent fins 28 of adjacent electronic modules 10 and to dissipate from separate, adjacent electronic modules 10. Opposing thermally conductive fins 28 are interleaved to facilitate cooling, to remove heat from electronic modules 10. An arrangement of opposing fins 28 is such that fins 28 of a first electronic module 10a extend between parallel fins 28 of a second electronic module 10b. Fins 28 extend a distance from base 26 that maximizes surface area of heat spreader 14 and allows fluid flow between interdigitated fins 28 and bases 26. Fins 28 can be arranged to provide selectively directed airflow to accommodate specific component heat generating capacity and specific cooling. Fins 28 of heat spreader 14 provide for directed airflow and increased surface area to maximize packing density of electrical components 24 on electronic module 10 while providing effective thermal management.

Fins 28 can extend linearly from a first end 30 to an opposing second end 32 of electronic module 10. Alternatively, fins 28 can be contoured to direct cooling flow over components 24 that are desirably cooled such as high powered or heat sensitive components, rather than over relatively unpopulated portions of the DIMM that may be less desirable to cool. Fluid flow over components 24 can be segregated with contoured fins 28 to direct fluid flow over specific desired components 24, such as heat sensitive components, and around hot components, while a hot channel is routed past the heat sensitive component, over the hot components(s), and steered around rather than over other heat sensitive components. The channel may be configured around multiple dimensions (i.e., three dimensionally) to include deeper or shallower fins 28 to route around components 24 such that the channel formed between components 24 can be compressed on a vertical dimension to leave room for a segregated channel to expand and route over component 24. Adjacent DIMMs 10 share volumetric space with each other through interdigitated fins 28 within the processor. Fins 28 of adjacent electronic modules 10 cross extend into shared space between printed circuit boards 12 of electronic modules 10.

The flow path is initiated at a first end 30 of the at least two electronic modules 10. In one example, the flow is initiated by a fan either pushing or pulling the fluid over surfaces of the electronic modules 10. Cool air or coolant passes around and between fins 28, cooling electronic components 24 of the electronic modules 10 as heat is transferred from the surfaces of fins 28 and base 26 of heat spreader 14. Flow passes over the surfaces of interdigitated adjacent fins 28 of adjacent electronic modules 10, passing between the electronic modules 10 and exiting at second end 32 of electronic modules 10. The fluid passing from the first end 30 is heated by heat transferred from the electronic components 24 closest to the first end, and is accordingly pre-heated when passing over components closer to the second end 32.

An electronic device, such as an electronic subsystem 36, including a plurality of electronic components 24 to be cooled is illustrated in FIG. 3. Electronic module 10 is inserted into a connector slot 34 within an electronics subsystem 36. Fins 28 share common volumetric space 38 between connector slots 34. For ease of assembly, electronic modules 10 are assembled, or stacked together so that fins 28 of adjacent electronic modules 10 are interdigitated and inserted into processor connector slots 34 as an assembled grouping of electronic modules 10. Electronic modules 10 can be grouped together and inserted into connector slots 34 together. The grouped electronic modules 10 are configured to occupy typical module connector slots 34 and do not increase space between connector slots 34 or memory modules 10. Regions between interdigitated adjacent fins 28 form, or define, fluid flow channels.

The interdigitated electronic modules 10 can include a false, or dummy, memory module (i.e., without electronic components) to provide desired flows for cooling components 24 on adjacent electronic modules 10. For example, the last in a series of electronic modules 10 inserted into slots 34 can be included to interdigitate with fins 28 of the adjacent electronic module 10 to provide the desired flows at the edge of the group. The interdigitated electronic modules 10 can be coordinated with other components of the electrical system or subsystem, such a processor heat sink's configuration, to provide space to the electronic modules 10 and fluid flow channel at the edge of the group of electronic modules 10.

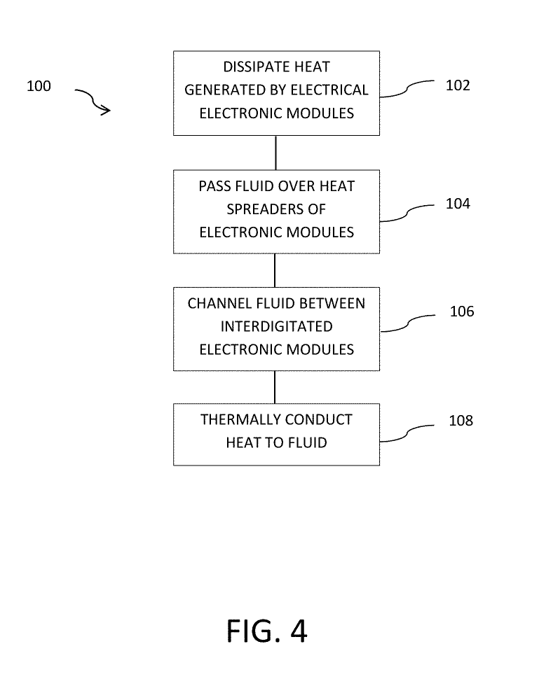

FIG. 4 illustrates a method 100 in accordance with aspects of the present disclosure. At 102, heat generated by at least two electronic modules is dissipated. The at least two electronic modules are positioned adjacently. The at least two electronic modules each include a printed circuit board, electronic components disposed on the printed circuit board, and a heat spreader disposed over the electronic components on the printed circuit board, the heat spreader including a base and heat spreading fins extending away from the base, the fins of the adjacent at least two electronic modules interdigitated. At 104, fluid is passed over the heat spreader from a first end of the electronic module to a second end of the electronic module. At 106, fluid is channeled between the fins and the base of adjacent interdigitating electronic modules from the first end to the second end. At 108, heat is thermally conducted from the electronic components, through the fins and the base to the fluid.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

1. An electronic device, comprising:
at least two electronic modules, each electronic module comprising:
a printed circuit board having a first surface and a second surface;
heat generating components disposed on the first and the second surfaces of the printed circuit board; and
a heat spreader disposed on the heat generating components opposite the printed circuit board on each of the first and second surfaces of the printed circuit board, the heat spreader including a base and fins extending from the base,
wherein the fins on a first side of a first of the at least two electronic modules extend toward a second of the at least two electronic modules, and fins on a second side of the second of the at least two electronic modules extend toward the first of the at least two electronic modules to interdigitate and share volumetric space between the printed circuit boards of the first and second of the at least two electronic modules.

2. The electronic device of claim 1, wherein the at least two electronic modules are memory modules.

3. The electronic device of claim 1, wherein the at least two electronic modules are dual in-line memory modules.

4. The electronic device of claim 1, wherein the interdigitated fins define fluid channels between the first and the second of the at least two electronic modules.

5. The electronic device of claim 1, wherein the fins are interdigitated to direct cooling to select heat generating components.

6. The electronic device of claim 1, wherein the fins and the base are formed of a thermally conductive material.

7. An electronic device, comprising:
a processor including memory module slots; and
at least two electronic modules disposed in the memory module slots, each electronic module comprising:
a printed circuit board having a first side and a second side;
heat generating components disposed on the first and the second sides of the printed circuit board; and
a heat spreader positioned on each of the first and second sides of the printed circuit board, the heat spreader including a base surface extending along an outer surface of the heat generating components and fins extending from the base surface along the first side and the second side in a direction away from the heat generating components, the fins extending from a first side of a first of the at least two electronic modules interdigitate with the fins extending from a second side of a second of the at least two electronic modules.

8. The electronic device of claim 7, wherein the fins and the base surface of the heat spreader are formed contiguously on each of the first and second sides.

9. The electronic device of claim 7, wherein the fins extending from a first side of a first of the at least two electronic modules interdigitate with the fins extending from a second side of a second of the at least two electronic modules to form fluid channels between the at least two electronic modules.

10. The electronic device of claim 9, wherein the fluid channels are configured to provide fluid flow over a surface of the heat spreader including the fins from a first end to a second end of the electronic module.

11. The electronic device of claim 7, wherein the at least two electronic modules are disposed in adjacent memory module slots.

12. A method, comprising:
dissipating heat generated by at least two electronic modules, the at least two electronic modules positioned adjacently, the at least two electronic modules each include a printed circuit board, electronic components disposed on the printed circuit board, and a heat spreader disposed over the electronic components on the printed circuit board, the heat spreader including a base and heat spreading fins extending away from the base, the fins of the adjacent at least two electronic modules interdigitated, wherein the dissipating comprises:
passing fluid over the heat spreader from a first end of the electronic module to a second end of the electronic module;
channeling fluid between the fins and the base of adjacent interdigitating electronic modules from the first end to the second end; and
thermally conducting heat from the electronic components, through the fins and the base to the fluid.

13. The method of claim 12, wherein channeling fluid includes directing the fluid over select heat sensitive electronic components.

14. The method of claim 12, wherein channeling fluid includes directing pre-heated fluid around select electronic components.

15. The method of claim 12, wherein the fluid is air.
